(19) United States
(12) Patent Application Publication
(10) Pub. No.: US 2010/0149781 A1
(43) Pub. Date: Jun. 17, 2010

(54) WATERPROOF COMMUNICATION APPARATUS

(75) Inventors: TE HUA WU, Hsinchu (TW); YI HSIANG HUANG, Hsinchu (TW)

Correspondence Address: WPAT, PC;INTELLECTUAL PROPERTY ATTORNEYS, 2030 MAIN STREET, SUITE 1300, IRVINE, CA, 92614, US

(73) Assignee: MICROELECTRONICS TECHNOLOGY INC., HSINCHU (TW)

(21) Appl. No.: 12/572,679

(22) Filed: Oct. 2, 2009

(30) Foreign Application Priority Data
Dec. 16, 2008 (TW) 097222513

(51) Int. Cl. H05K 9/00

(52) U.S. Cl. 361/818

(57) ABSTRACT

An electromagnetic interference shielding apparatus for a signal transceiver comprises a metal cover, a chassis, adhesive, and a waveguide output hole. A first combination portion having a first curved section is disposed on the edge of the metal cover. The first curved section of the first combination portion includes at least one opening The edge of the chassis includes a second combination portion having a groove corresponding to the first combination portion. A lateral slot is at the location of the second combination portion corresponding to the opening The adhesive combines the first combination portion and the second combination portion. A waveguide is disposed in the chassis, and extends to the exterior of the chassis through the waveguide output hole. A flat tool can be inserted into a space between one of the openings and a corresponding lateral slot to separate the metal cover from the chassis.

### BACKGROUND OF THE INVENTION

(A) Field of the Invention

The present invention relates to an electromagnetic interference shielding apparatus for a signal transceiver. More particularly, the present invention relates to an electromagnetic interference shielding apparatus applicable to a high-frequency signal transceiver.

(B) Description of the Related Art

Generally, it is difficult for microwave signals transmitted between the earth and artificial satellites to pass through walls, roofs, or even glass windows. Therefore, satellite signal transceivers are located outdoors with antennas pointing directly at artificial satellites to obtain optimal transmission efficiencies. FIG. 1A shows a conventional shielding apparatus 10 of a block upconverter (BUC) accommodating an outdoor satellite signal transceiver (not shown), which is mainly used to protect the outdoor satellite signal transceiver from damage caused by the environment (e.g., rain, moisture, etc.). FIG. 1B is a partial cross-sectional view of the shielding apparatus 10. The shielding apparatus 10 includes an upper cover 11, a chassis 12, and a waveguide output hole (not shown). When the shielding apparatus 10 is applied to protect the outdoor satellite signal transceiver, the outdoor satellite signal transceiver is placed in an internal space 15 formed by the cover 11 and the chassis 12. To enable the satellite signal transceiver to be used outdoors and be waterproof, the shielding apparatus 10 utilizes an O-ring 13 disposed between the cover 11 and the chassis 12, and employs a plurality of screws 14 to combine the cover 11 and the chassis 12. Meanwhile, pressure is applied to the O-ring 13 to deform the O-ring 13, thus realizing the waterproof function. However, the conventional shielding apparatus 10 has the following disadvantages: (1) the cover 11 and the chassis 12 are generally fabricated by die casting; when they are combined by the plurality of screws 14 and the O-ring 13, the slit between rough combined surfaces 111 and 121 cannot effectively stop the leakage of high-frequency signals (e.g., signals belonging to the Ku band, C band, or Ka band), and cannot effectively shield the interference of external noises; and (2) when disassembling or assembling the upper cover 11 and the chassis 12, the screws 14 must be loosened or fastened one by one, increasing the time and cost consumed by assembly and testing.

FIG. 2A shows the shielding apparatus of a transceiver according to Taiwanese patent No. M315472. The shielding apparatus 20 includes a metal cover 21, a chassis 22 having a waveguide output hole 25, two recess portions 212, and an adhesive 23 (also see FIG. 2B). A waveguide 90 is disposed in the chassis 22, and extends to the exterior of the chassis 22 through the waveguide output hole 25. FIG. 2B is a cross sectional view of the metal cover 21 and the chassis 22, respectively, taken along a sectional line A-A of FIG. 2A. The first curved section 211 of the metal cover 21 is interlocked with the groove 214 of the chassis 22. The metal cover 21 and the chassis 22 are tightly combined by filling adhesive 23 into the groove 214 to protect the signal transceiver from the interference of penetrating electromagnetic waves. Furthermore, neither rain nor moisture can penetrate into the interior of the signal transceiver. When the signal transceiver needs to be checked and repaired, the metal cover 21 and the chassis 22 are difficult to separate from each other. The space of the groove 214 after the engagement of the first curved section 211 is too small to permit insertion of a tool into the space. The hat portion of the metal cover 21 is secured by a clamp tool, and the metal cover 21 is removed from the adhesive 23 in the groove 214 by applying sufficient pulling force. When the metal cover 21 is separated from the chassis 22, the hat portion of the metal cover 21 is likely to be deformed by the clamping force. That is, the metal cover 21 cannot be assembled with the chassis 22. It is obvious that such a conventional design cannot meet the requirement of disassembly and reassembly. Due to the difficulty of disassembly, the metal cover 21 is likely to be scrapped so as to increase the cost.

### SUMMARY OF THE INVENTION

An aspect of the present invention is to provide a shielding apparatus for a signal transceiver. The bended edges of a metal cover are interlocked with a chassis, and the metal cover and the chassis are assembled by adhesive. Internal RF (radio frequency) signals are effectively isolated to prevent leakage, and interference from external noise is also blocked. Accordingly, a sealed connection is obtained so as to prevent external moisture from entering. The bended edges of the metal cover have several openings, and the groove also has several corresponding lateral slots. A flat tool can be inserted into a space between one of the openings and its corresponding lateral slot to separate the metal cover from the chassis. Therefore, the shielding apparatus for a signal transceiver is easily assembled and disassembled, and has low material cost.

The present invention discloses an electromagnetic interference shielding apparatus for a signal transceiver, which comprises a metal cover, a chassis, adhesive, and a waveguide output hole. A first combination portion having a first curved section is disposed on the edge of the metal cover. The first curved section of the first combination portion includes at least one opening The edge of the chassis includes a second combination portion having a groove corresponding to the first combination portion. A lateral slot is at the location of the second combination portion corresponding to the opening. The adhesive combines the first combination portion and the second combination portion. A waveguide is disposed in the chassis, and extends to the exterior of the chassis through the waveguide output hole. A flat tool can be inserted into a space between one of the openings and its corresponding lateral slot to separate the metal cover from the chassis.

### BRIEF DESCRIPTION OF THE DRAWINGS

The objectives and advantages of the present invention will become apparent upon reading the following description and upon reference to the accompanying drawings in which:

FIG. 1A shows a conventional shielding apparatus 10 of a block upconverter (BUC) accommodating an outdoor satellite signal transceiver;

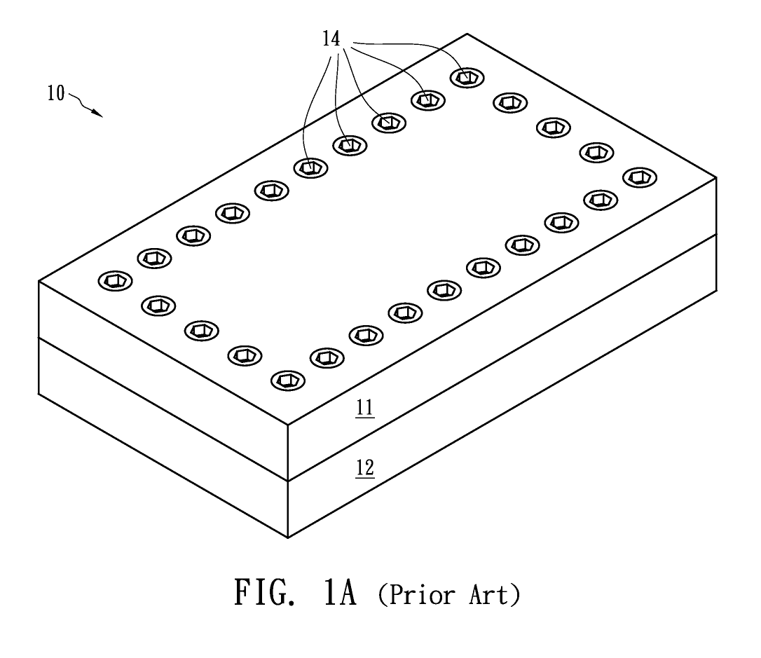

FIG. 1B is a partial cross-sectional view of the shielding apparatus 10;

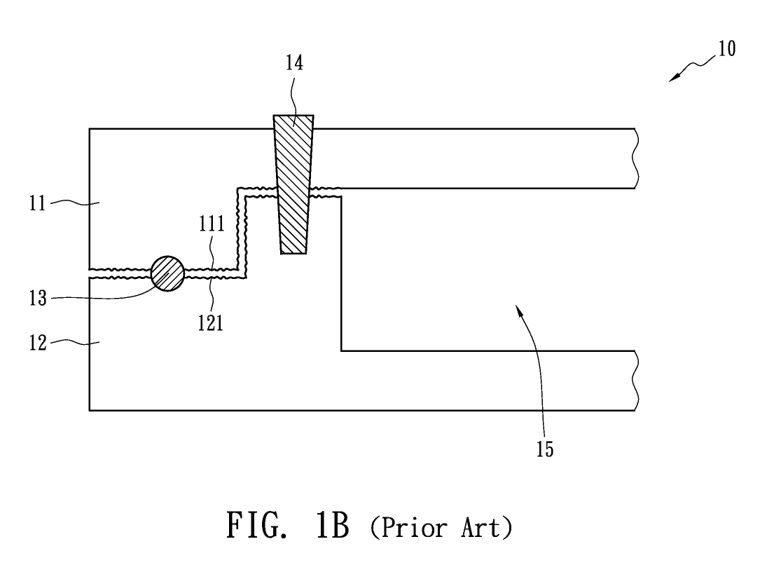

FIG. 2A shows the shielding apparatus of a transceiver according to Taiwanese patent No. M315472;

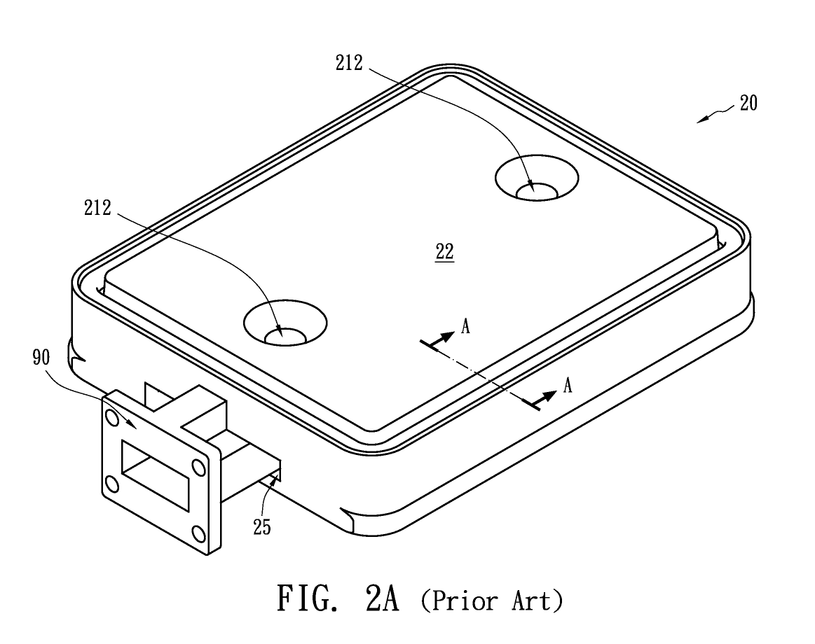

FIG. 2B is a cross-sectional view of the metal cover and the chassis, respectively, taken along a sectional line A-A of FIG. 2A;

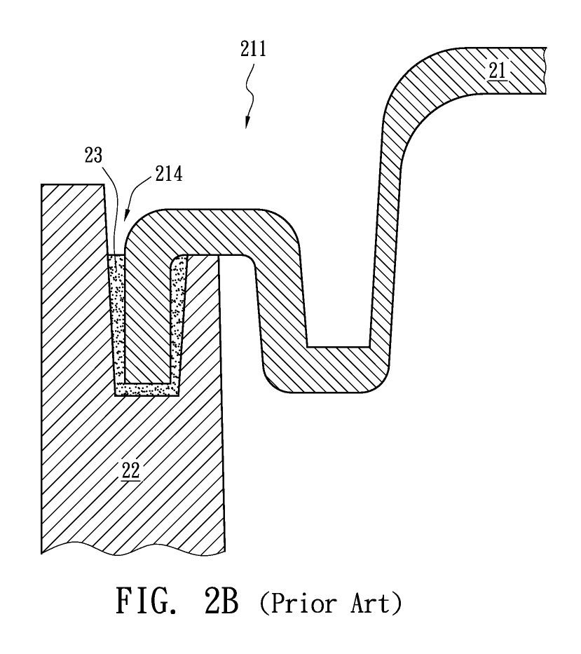

FIG. 3 shows an exploded diagram of an interference shielding apparatus for a signal transceiver in accordance with an embodiment of the present invention;

FIG. 4 shows an assembly diagram of an interference shielding apparatus for a signal transceiver in accordance with an embodiment of the present invention;

FIG. 5A is a cross-sectional view of the metal cover and the chassis, respectively, taken along a sectional line B-B of FIG. 4; and

FIG. 5B shows a tool inserted into a space enclosed by an opening and a corresponding lateral slot to separate the metal cover and the chassis from each other.

### DETAILED DESCRIPTION OF THE INVENTION

The following descriptions illustrate a waterproof communication apparatus of the present invention through the drawings. Regarding the schematic diagrams disclosed by embodiments, the present invention is only illustrated by diagrams, but the scope of the present invention is not limited by the diagrams. These schematic diagrams show the structure of the apparatus, but the dimensions of the diagrams cannot limit the scope of the present invention. The aforesaid statements are provided for further understanding before the following embodiments are introduced.

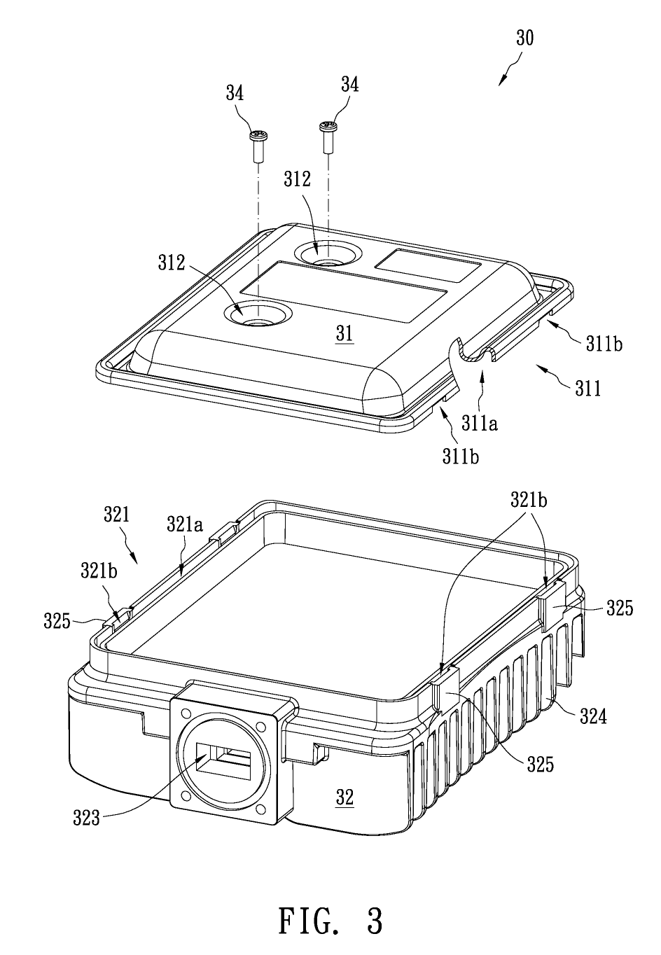

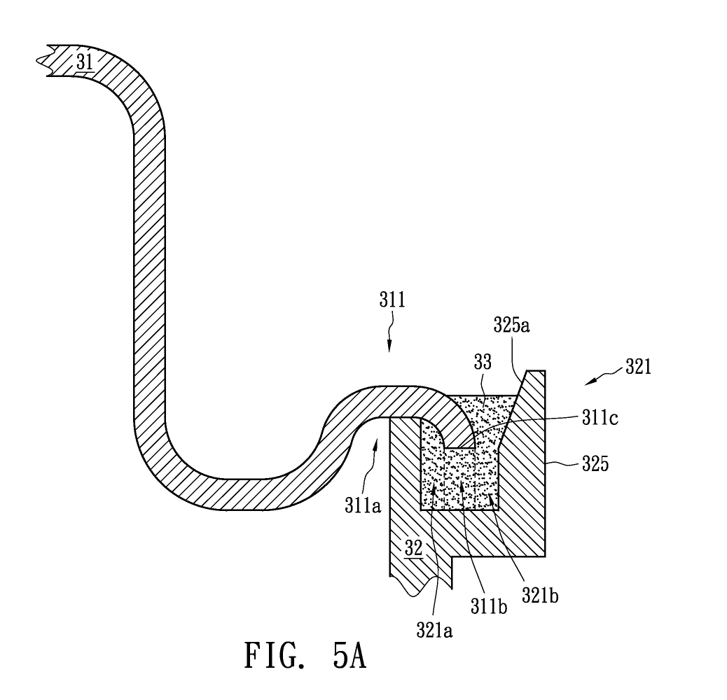

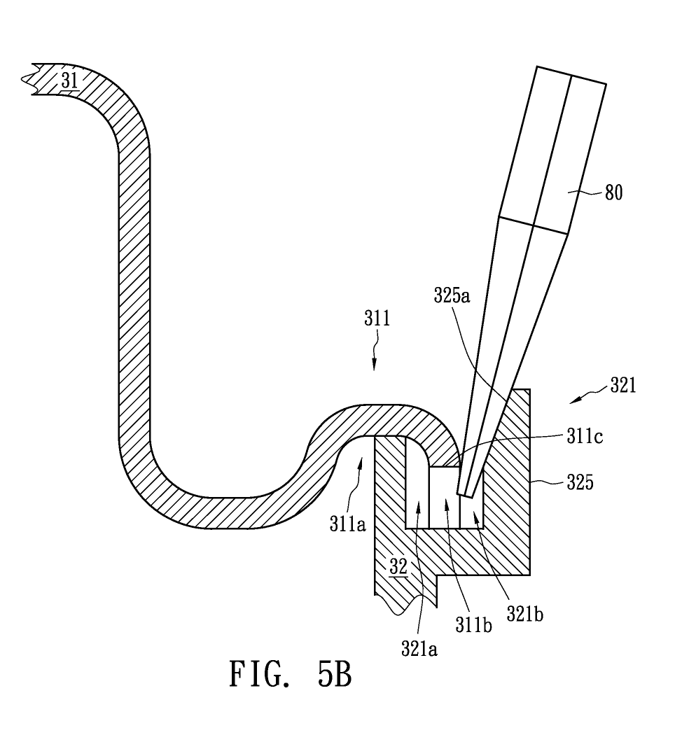

FIG. 3 shows an exploded diagram of an interference shielding apparatus for a signal transceiver in accordance with an embodiment of the present invention. The shielding apparatus 30 includes a metal cover 31, a chassis 32 having a waveguide output hole 323, two recess portions 312, and an adhesive 33 (See FIG. 5A). A first combination portion 311 having a first curved section 311a is disposed on the edge of the metal cover 31. The first curved section 311a of the first combination portion 311 includes four openings 311b which are respectively and symmetrically disposed on two opposite sides of the metal cover 31. The edge of the chassis 32 includes a second combination portion 321 having a groove 321a corresponding to the first combination portion 311. Each of the lateral slots 321b is at the location of the second combination portion 321 corresponding to one of the openings 311b. The lateral slot 321b is a groove 321a extending towards the lateral of the chassis 32. A lateral convex wall 325 outwards encloses the lateral slot 321b. A waveguide (not shown) is disposed in the chassis 32, and extends to the exterior of the chassis 32 through the waveguide output hole 323.

The adhesive combines the first combination portion 311 and the second combination portion. A waveguide is disposed in the chassis, and extends to the exterior of the chassis through the waveguide output hole. A flat tool can be inserted into a space between one of the openings and its corresponding lateral slot to separate the metal cover from the chassis.

Two fastening parts 34 (e.g., screws) are respectively put into the recess portions 312, and are fixed to other members (not shown) inside the chassis 32. The metal cover 31 and the chassis 32 can be tightly combined with each other. In order to enhance the thermal dissipation of the chassis 32, a plurality of heat dissipation fins 324 can be disposed on the bottom of the chassis 32.

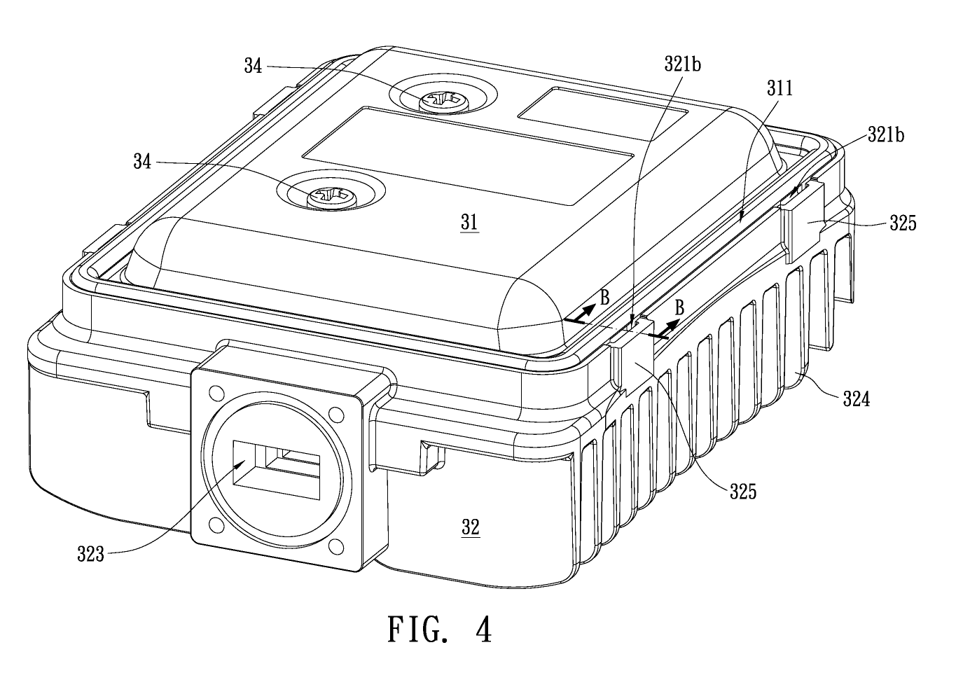

FIG. 4 shows an assembly diagram of an interference shielding apparatus for a signal transceiver in accordance with an embodiment of the present invention. The first curved section 311a of the first combination portion 311 and the groove 321a of the second combination portion 321 are engaged with each other. The metal cover 31 and the chassis 32 are tightly secured together by filling adhesive 33 into the groove 321a. The two fastening parts 34 apply sufficient compression force to the metal cover 31 and the chassis 32 along the direction perpendicular to the connection plane between them. Accordingly, external electromagnetic waves cannot penetrate into the interior and interfere with the signal transceiver. Furthermore, adhesive 33 is filled into the recess portions 312 to cover the fastening parts 34 so that rain or moisture cannot permeate into the interior.

FIG. 5A is a cross-sectional view of the metal cover and the chassis, respectively, taken along a sectional line B-B of FIG. 4. The sectional line B-B passes through the groove 321a and the lateral slot 321b, and this figure shows that the adhesive 33 is filled in the groove 321a and the lateral slot 321b. The adhesive 33 is also filled in the opening 311b, and the free end 311c of the first curved section 311a is covered by the adhesive 33. An inclined surface 325a is on the inner wall of the lateral convex wall 325. The opening of the lateral slot 321b has a tapered profile.

FIG. 5B shows a tool inserted into a space enclosed by an opening and a corresponding lateral slot to separate the metal cover and the chassis from each other. Before the shielding apparatus is separated, a screwdriver is used to loosen the fastening parts 34 and remove them from the metal cover 31. A tool 80 with a flat tip is inserted into the lateral slot 321b, and extends the interior of the lateral slot 321b along the tapered opening surrounded by the inclined surface 325a. A surface of the tool 80 is against the inclined surface 325a. The tip of the tool 80 pierces the adhesive 33 to push the free end 311c of the first curved section 311a. The inclined surface 325a is the fulcrum for the tool 80. The free end 311c is pulled out from the adhesive 33 by rotating the tool 80 in a counterclockwise direction. Similarly, the tool 80 is also inserted into the other three lateral slots 321b, and force is applied to remove the metal cover 31. Accordingly, the metal cover 31 and the chassis 32 are easily separated from each other while not deforming the metal cover 31. Such a separating operation is performed merely by a simple tool 80 such as a slotted screwdriver. No clamping tools are needed to separate the metal cover 31 from the chassis 32.

The above-described embodiments of the present invention are intended to be illustrative only. Those skilled in the art may devise numerous alternative embodiments without departing from the scope of the following claims.

What is claimed is:

1. An electromagnetic interference shielding apparatus for a signal transceiver, comprising:
a metal cover including a first combination portion having a first curved section on edges of the metal cover, wherein the first curved section includes at least one opening;
a chassis including a second combination portion having a groove corresponding to the first combination portion, a lateral slot being at the location of the second combination portion corresponding to the opening; and
adhesive combining the first combination portion and the second combination portion;
wherein space enclosed by the opening and the corresponding lateral slot allows a tool to be inserted therein, and the tool is applied against the opening and the lateral slot to separate the metal cover and the chassis.

2. The electromagnetic interference shielding apparatus for a signal transceiver of claim 1, wherein the second combination portion further includes a lateral convex wall surrounding the lateral slot, and the space is between the opening and the lateral convex wall.

3. The electromagnetic interference shielding apparatus for a signal transceiver of claim 2, further comprising an inclined surface on a surface of the lateral convex wall toward the opening

4. The electromagnetic interference shielding apparatus for a signal transceiver of claim 1, wherein the transmitted signal of the signal transceiver belongs to a Ku band, a C band, or a Ka band.

5. The electromagnetic interference shielding apparatus for a signal transceiver of claim 1, wherein the apparatus further comprises a plurality of fastening parts, the metal cover comprises a plurality of recess portions, and the fastening parts are respectively inserted into the recess portions to combine the metal cover with the chassis.

6. The electromagnetic interference shielding apparatus for a signal transceiver of claim 1, wherein the fastening parts are screws.

7. The electromagnetic interference shielding apparatus for a signal transceiver of claim 1, wherein the metal cover is a rectangular flat structure having four rounded corners.

8. The electromagnetic interference shielding apparatus for a signal transceiver of claim 1, wherein the adhesive is filled in the groove of the second combination portion.

9. The electromagnetic interference shielding apparatus for a signal transceiver of claim 1, further comprising a plurality of thermal dissipation fins disposed on the bottom of the chassis.

10. The electromagnetic interference shielding apparatus for a signal transceiver of claim 1, wherein the chassis further comprises a waveguide output hole allowing a waveguide disposed in the chassis to extend to the exterior of the chassis.
